(19) United States
(12) Patent Application Publication
(10) Pub. No.: US 2010/0001741 A1
(43) Pub. Date: Jan. 7, 2010

(54) Method for Locating Pipe Leaks

(76) Inventor: Guenther Bier, Vienna (AT)

Correspondence Address: EDELL, SHAPIRO & FINNAN, LLC, 1901 RESEARCH BOULEVARD, SUITE 400, ROCKVILLE, MD, 20850, US

(21) Appl. No.: 12/511,451

(22) Filed: Jul. 29, 2009

Related U.S. Application Data
(63) Continuation of application No. PCT/EP2008/050555, filed on Jan. 18, 2008.

(30) Foreign Application Priority Data
Jan. 29, 2007 (AT) 138/2007

(51) Int. Cl. G01R 27/00; G06F 19/00

(52) U.S. Cl. 324/600; 702/57

(57) ABSTRACT

A method for identifying leaks in pipes employs an electrical conductor extending longitudinally along a pipe between first and second measuring points. A measurement signal in the form of a temporally variable voltage is applied to the electrical conductor, and the impedance behavior of the conductor is used to determine the presence of a leak. A first measurement signal in the form of a temporally variable voltage is transmitted from the first measuring point to the second measuring point via the electrical conductor, and both measuring points evaluate the impedance of the electrical line. The second measuring point transmits a first result signal with the results of the impedance evaluation to the first measuring point via the same electrical conductor such that the first result signal temporally overlaps the first measurement signal, and the first measurement signal and the first result signal are present in non-overlapping frequency bands.

### CROSS REFERENCE TO RELATED APPLICATIONS

This application is a continuation of International Application No. PCT/EP2008/050555, filed on Jan. 18, 2008, entitled “Method for Locating Pipe Leaks,” which claims priority under 35 U.S.C. §119 to Application No. AT 138/2007 filed on Jan. 29, 2007, entitled “Method for Locating Pipe Leaks,” the entire contents of which are hereby incorporated by reference.

### FIELD OF THE INVENTION

The invention relates to a method for determining and optionally locating leaks in pipes for the transport of liquid or gaseous media by use of at least one electrical conductor extending along the longitudinal extension of the pipe from a first measuring point to a second measuring point, wherein a measurement signal in the form of a temporally variable voltage is applied to the electrical conductor, and the impedance behavior of the conductor is used to determine the presence of a leak.

The invention further relates to a measuring point for determining and optionally locating leaks in pipes for the transport of liquid or gaseous media, the measuring point being connected to at least one electrical conductor extending along the longitudinal extension of the pipe, and having a signal generator for a measurement signal in the form of a temporally variable voltage, wherein the measurement signal is suitable for investigating the impedance behavior of the electrical conductor which is altered by a leak, and includes a transmitter which injects the measurement signal into the electrical conductor.

### BACKGROUND

Pipes for the transport of liquid or gaseous media are widely used, and usually run underground. Such pipes may be water line pipes or district heating pipes, for example, whereby in the latter case the transport medium may also be present in the gaseous state in the form of steam. To minimize escape of the medium, and in the case of district heating pipes, to minimize energy losses, due to leaks, it is necessary to detect such leaks as quickly as possible. To minimize the subsequent level of effort and cost to eliminate the damage, it is also desirable to locate these leaks as accurately as possible.

Various methods are known for determining and locating leaks. One possibility, for example, lies in measuring the time echo of pulsed test signals in electrical monitoring conductors provided in the immediate vicinity of the pipe. For this purpose, for example, the pipe in which the medium is transported is encased in a plastic shell, in which the electrical conductor is foamed in. The plastic shell in turn is provided with a waterproof protective cover. This system is also referred to below as a “pipe composite.” The wetting of the plastic shell resulting from escape of the transport medium reduces the insulation resistance between the pipe and the electrical monitoring conductor or between the monitoring conductors, and thus represents a low-impedance site at which the voltage pulses are reflected. The transit time of the echo may be used to determine the distance of the leak from the injection site for the test signal. Even when corresponding low-impedance conductors such as copper wires are used, a leak cannot be reliably located until there is relatively intense wetting, and thus, after the medium has been leaking from the pipe for a comparatively long time. In addition, evaluation and interpretation of the time echo has proven to be complicated and difficult.

Another possibility for determining a leak lies essentially in the use of a resistance measuring bridge. In this method, the electrical resistance between a high-impedance conductor, such as a nickel-chromium conductor, and a low-impedance conductor, such as a copper wire or the conductive pipe, is monitored. When the plastic shell of the pipe is wetted as the result of escaping transport medium the insulation resistance is reduced, and the leak is located according to the principle of the unloaded voltage divider. For this purpose a threshold value is defined for the electrical resistance, whereby an alarm signal is generated when the value drops below this threshold value, and the leak is located. This method has proven to be sensitive enough to allow detection of even small changes in resistance, and thus, rapid determination of defects. In practice, however, it has been found that this method produces an unacceptably high number of false alarms, thus increasing the maintenance costs for the pipe section due to the structural intervention which turns out to be unnecessary.

Therefore, in Austrian Patent AT 501 758 a new measuring method was proposed in which the impedance behavior between the start and end points of a conductor inserted into the pipe is determined for an intact pipe, and at later points in time the impedance behavior is determined at the same test voltages and compared to the impedance behavior that is known for the intact pipe, and the deviations in the impedance behavior, determined at the later points in time, from that of intact pipe are used to ascertain the presence of a leak. The impedance behavior between the start and end points of the electrical conductor for an intact pipe may thus be determined for multiple alternating voltage amplitudes and frequencies, which is not possible when just monitoring of a threshold value is carried out. In this manner a test program in which, for example, impedance values at different voltages and frequencies, i.e., the “impedance behavior,” are determined and evaluated may be automatically conducted at fixed time intervals.

Within the scope of this method it is also possible to include empirical values, obtained over the service life of the pipe section, in the determination of the impedance behavior for intact pipe, such as when cyclical changes or a gradual change in the impedance behavior are observed. The method according to AT 501 758 is based on the finding that the impedance behavior of the overall system composed of the pipe, electrical monitoring conductors and their connection points, separating filler material, and the voltage sources and voltage measuring instruments is not constant over the service life of the pipe section, even though the pipe in which the medium is transported is still intact. Instead, as the result of damage to the pipe composite and the associated entry of moisture from outside the pipe composite, or also temperature changes, for example, variations in the moisture level inside the pipe composite occur without the pipe being defective. Furthermore, damage may also occur in the overall electrical system of the monitoring conductors, for example in the connecting points for the conductors, which cause an apparent decrease in the insulation resistance due to a reduction in the volume resistance. If the integrity of the pipe is then assessed on the basis of a comparison with a previously defined threshold value, in particular on the basis of detection of a value that is below this threshold value, a leak may be incorrectly indicated although the pipe is still intact.

A further consideration with regard to the method according to AT 501 758 is that the interpretation of a leak as merely the site of a short circuit is not adequate. Rather, the method is based on the concept that the filler material which separates the at least one monitoring conductor and the pipe represents a dielectric, having complex electrolytic and sometimes galvanic properties, which changes over the course of the operating period. Thus, it is not the measurement of just a resistance value and comparison of same to a threshold value that it is the focus of the observations; rather, the “impedance behavior” of the overall system is investigated. Namely, it has been shown that gradual changes in the impedance behavior due to factors other than a leak may definitely be distinguished from changes resulting from actual leaks.

In this known method, however, for a leak determination it is necessary for the two measuring points to alternatingly transmit a measurement signal which is analyzed at the respective opposite side of the measuring system. For this purpose, a first measuring point generates a first measurement signal and evaluates the impedance distribution at the input site at the start point of a pipe section where it is injected as an input signal. At the end point of the pipe section the first measurement signal is subsequently measured as a first response signal. Depending on the first response signal, a second measuring point then generates a second measurement signal which corresponds to the first measurement signal and which is injected at the end point of a monitoring conductor as a second input signal. This second input signal is measured at the start point as a second response signal.

However, this method has the disadvantage that, because of the alternating measurements and evaluation phases, it requires a complex process sequence control system which correspondingly specifies the activity of the involved measuring points in their time sequence. Furthermore, the transmission of the measurement signals between two measuring points must always be carried out in alternation, thus preventing simultaneous measurement of a pipe section. As a result, absolute or process-related measurement errors may arise which reduce the accuracy of the leak location.

### SUMMARY

The object of the invention, therefore, is to implement a method which avoids these disadvantages. A particular aim is to simplify the process sequence for the measurement while at the same time increasing the measurement accuracy.

Described herein is a method for determining and optionally locating leaks in pipes for the transport of liquid or gaseous media by use of at least one electrical conductor extending along the longitudinal extension of the pipe from a first measuring point to a second measuring point, wherein a measurement signal in the form of a temporally variable voltage is applied to the electrical conductor, and the impedance behavior of the conductor is used to determine the presence of a leak. The invention provides that a first measurement signal in the form of a temporally variable voltage is transmitted from the first measuring point to the second measuring point via the electrical conductor, and both measuring points evaluate the impedance of the electrical line, wherein by use of a first result signal the second measuring point transmits the result of the impedance evaluation to the first measuring point via the same electrical conductor so that the first result signal temporally overlaps the first measurement signal, and the first measurement signal and the first result signal are present in non-overlapping frequency bands. Alternating voltage is used in particular as a temporally variable voltage, although more complex measurement signals, such as pulse sequences of variable pulse shape, frequency, or amplitude, are also possible. The referenced frequency bands are also referred to below as “transmission channels.”

The second measuring point transmits a second measurement signal in the form of a temporally variable voltage to the first measuring point via the same electrical conductor, and both measuring points evaluate the impedance of the electrical line, wherein by use of a second result signal the first measuring point transmits the result of the impedance evaluation to the second measuring point via the same electrical conductor so that the second result signal temporally overlaps the second measurement signal, and the two measurement signals and the second result signal are respectively present in non-overlapping frequency bands. This further increases the accuracy of the leak determination, since the impedance of the electrical conductor is measured from two sides but on different transmission channels.

Thus, the first measuring point has not only the result of the impedance measurement at the first measuring point, but also has the result at the second measuring point. The leak may be accurately located with this information, such as via the ratio of the impedance values measured on both sides. Absolute or process-related measurement errors are eliminated by locating the leak from both sides. It is also important that the measurement and result signals are determined in a temporally overlapping manner and via the same electrical conductor. This is made possible by the fact that according to the invention the first measurement signal and the first result signal are present in non-overlapping frequency bands. As described in greater detail below, the process sequence for the measurement may be greatly simplified in this manner.

The measurement signals and the result signals from the respective transmitting measuring point are subjected to modulation, and at the respective other receiving measuring point are evaluated by synchronous demodulation. As described in greater detail below, the transmission quality of the transmitted measurement and result signals are thus improved, and the influence from spurious signals is minimized.

The first measuring point and the second measuring point are two consecutive measuring points in a plurality of measuring points situated along the electrical conductor, and the result of the impedance evaluation between the two consecutive measuring points is transmitted to at least one additional adjacent measuring point. As the result of this data transfer, after conclusion of all of the measurements each measuring point has all the data from every measuring point. This makes it possible, for example, for only one of the measuring points to have to be connected to a central control point in which the measurement data are collected, processed, and evaluated. However, it is also possible for all data to be read out locally at one of the measuring points. Alternatively, each of the measuring points could transmit its measurement data to a central control point in which the measurement data are collected, processed, and evaluated.

The data may be evaluated in the central control point for possible indications of leaks on the basis of trend analysis and/or pattern recognition, or also by use of self-learning systems, for example with the assistance of neural networks, as described in greater detail below. It may also be advantageous when the central control point can be accessed from the measuring points. In this manner the measurement data and analytical results may be interactively reviewed and interpreted from any location, in particular from any measuring point.

Further, a corresponding measuring point for determining and optionally locating leaks in pipes for the transport of liquid or gaseous media is described, which is connected to at least one electrical conductor extending along the longitudinal extension of the pipe, and which has a signal generator for a measurement signal in the form of a temporally variable voltage, wherein the measurement signal is suitable for investigating the impedance behavior of the electrical conductor which is altered by a leak, and which also includes a transmitter which injects the measurement signal into the electrical conductor. The invention provides that the measuring point also has a generator unit for a modulation signal and a base band signal unit for data transmission, as well as a modulator in which the measurement signal, baseband signal, and modulation signal are mixed. Thus, the basic functions include all sections necessary for transmitting data, i.e., baseband, modulator, transmitter, receiver, demodulator, and data separator. However, it is also possible for measurement signals to be directly modulated and injected into the electrical conductor. In such a case it is important to be able to carry out this operation without influence from the transmitted data. This may be ensured, for example, by means of different frequency ranges, or orthogonal signal processing. Alternatively, the use of suitable filters is also possible.

The measuring point also has a receiver for the modulated signals transmitted via the electrical conductor, and includes a demodulator and a data separator, the demodulator being connected to a measurement signal receiver for digital conversion of the measurement signal.

By use of a measuring point equipped in this manner it is possible to continuously monitor the line impedance during operation, and at the same time to communicate with other measuring points on the pipe. These functions may be used for processing the simultaneous measurement of impedance from both sides of the line.

### BRIEF DESCRIPTION OF THE DRAWINGS

The invention is described in greater detail below on the basis of exemplary embodiments, with reference to the accompanying figures which show the following:

FIG. 1 shows a schematic illustration of a system of measuring points on a pipe;

FIG. 2 shows the schematic structure of a measuring point;

FIG. 3 shows a diagram for illustrating the simultaneous transmission of a measurement signal and a result signal; and

FIG. 4 shows the schematic sequence of measurement and data transmission between the measuring points.

### DETAILED DESCRIPTION

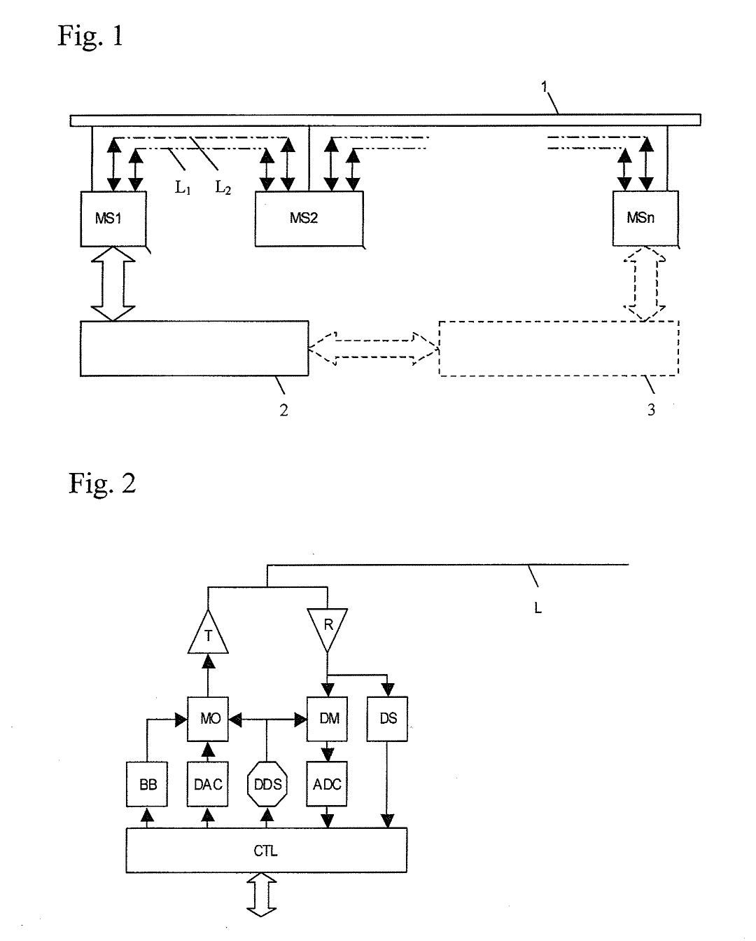

FIG. 1 shows a schematic illustration of a system of measuring points MSᵢ (i=1 . . . n) on a pipe 1. The pipe 1 is used for the transport of liquid or gaseous media, and is typically run over long distances so as to be difficult to access, for example underground. Such pipes may be water line pipes or district heating pipes, for example, whereby in the latter case the transport medium may also be present in the gaseous state in the form of steam. However, the method according to the invention is suitable for monitoring pipes for the transport of any type of media, provided that the transported medium is electrically conductive, whereby a conductivity of the transport medium of a few μS/cm is adequate.

The pipes 1 are usually steel or copper pipes, in the immediate vicinity of which electrical monitoring conductors L are provided. As an example, FIG. 1 illustrates two monitoring conductors L₁ and L₂. For this purpose, for example, the pipe 1 in which the medium is transported is encased by a thermally and electrically insulating shell in which the electrical conductor L is embedded, and is also enclosed by a waterproof protective cover. The thermally and electrically insulating material may be plastic, for example, such as PUR hard foam, glass, or mineral wool, or fiber insulation. The following discussion is based on use of a plastic shell.

In the dry state the plastic shell has electrically insulating properties. The wetting of the plastic shell which occurs as the result of escaping transport medium reduces the insulation resistance between the pipe 1 and the electrical monitoring conductor L₁ or L₂ or between the monitoring conductors L₁ and L₂, and thus represents a low-impedance site for which the altered electrical conditions may be used for detecting and locating the leak.

FIG. 1 shows the use of two monitoring conductors L₁ and L₂, although it is also possible to use only one conductor L, or multiple conductors Lᵢ, whereby the positioning of the monitoring conductors L inside the casing may vary. The conductors L₁ and L₂ represent a high-impedance conductor L₁, such as a nickel-chromium conductor, and optionally a low-impedance conductor L₂, such as a copper wire or a copper-nickel conductor. The electrical resistance between the high-impedance conductor L₁ and the low-impedance conductor L₂, and optionally also between the high-impedance conductor L₁ and the pipe 1, is monitored. When only one monitoring conductor L is used, the electrical resistance between the high-impedance conductor L and the conductive pipe 1 is monitored.

FIG. 1 also shows that the measuring points MSᵢ transmit their measurement data to a central control point 2 in which the measurement data are collected, processed, and evaluated. The data may be evaluated for possible indications of leaks on the basis of trend analysis and/or pattern recognition, or also by use of self-learning systems, for example with the assistance of neural networks. Noncritical long-term changes should be recognized as subcritical and sorted out. However, changes which indicate leaks are correspondingly clearly marked. In this manner, evaluations performed as the result of controlling interventions by the user are included in future decision processes in the indication and location of leaks. It is also advantageous when the central control point 2 can be accessed from the measuring points MSᵢ. In this manner the measurement data and analytical results may be interactively reviewed and interpreted from any location, in particular from any measuring point MSᵢ. It is thus possible for maintenance personnel to easily investigate possible fault events without direct influence from the control point 2. The control point 2 may therefore be unattended. Furthermore, one or more additional control points 3 may optionally be provided for carrying out these analytical tasks.

FIG. 2 shows the schematic structure of a measuring point MSᵢ for determining and optionally locating leaks in pipes 1, which is connected to at least one electrical conductor L extending along the longitudinal extension of the pipe 1, and which has a signal generator DAC for a measurement signal in the form of a temporally variable voltage. The measuring point MSᵢ also includes a transmitter T which injects the measurement signal into the electrical conductor L. Also provided according to the invention are a generator unit DDS for a modulation signal and a base band signal BB unit for data transmission, as well as a modulator MO in which the measurement signal, base band signal, and modulation signal are mixed. The measuring point MSᵢ also has a receiver R for the modulated signals transmitted via the electrical conductor L, as well as a demodulator DM and a data separator DS, the demodulator DM being connected to a measurement signal receiver ADC for digital conversion of the measurement signal. These components are coordinated by use of a control unit CTL. Thus, the basic functions include all sections necessary for transmitting data, i.e., base band signal unit BB, modulator MO, transmitter T, receiver R, demodulator DM, and data separator DS. However, it is also possible for measurement signals to be directly modulated and injected into the electrical conductor L. In such a case it is important to be able to carry out this operation without influence from the transmitted data. This may be ensured, for example, by means of different frequency ranges, or orthogonal signal processing. Alternatively, the use of suitable filters is also possible.

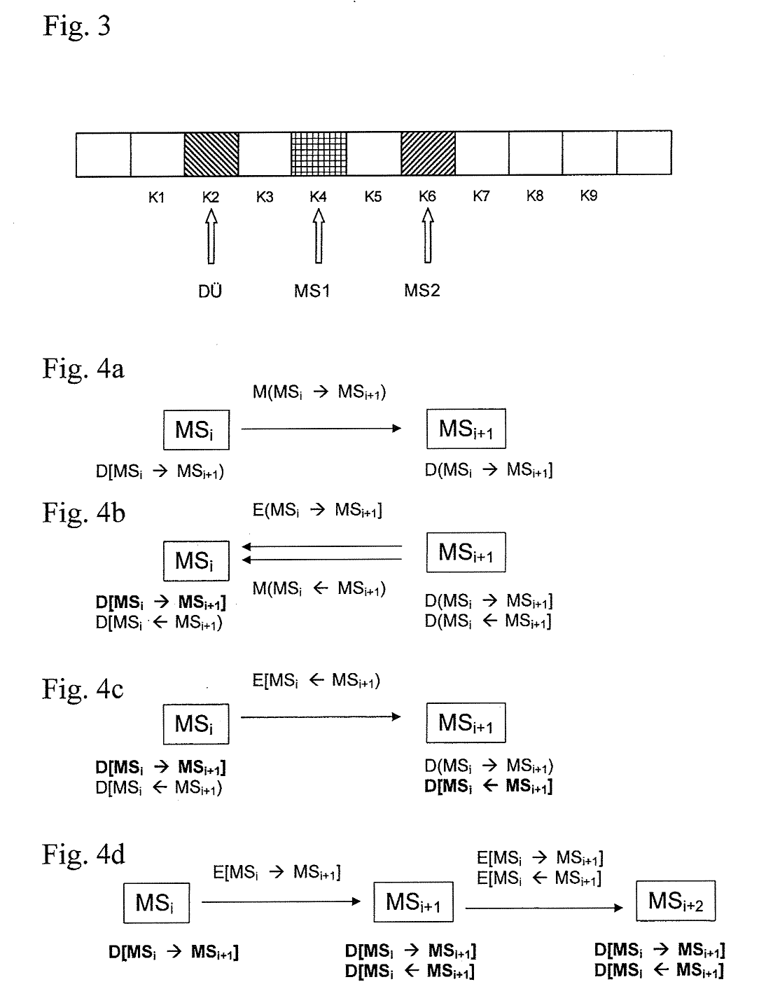

FIG. 3 schematically shows the function of the simultaneous measurement of two measuring points MSᵢ and MSⱼ, and transmission of the corresponding result signals. In the example shown in FIG. 3 it has been assumed, for example, that the data transmission DÜ takes place in transmission channel K2. For better selection, in each case an appropriate number of channels (in this example, one) is left open in order to minimize the use of filters. It is further assumed that in the affected segment of the conductor L a measuring point MS₁ is present at the start, and a measuring point MS₂ is present at the end, of the conductor L. Measuring point MS₁ transmits its measurement signal to channel K4 and evaluates the impedance of the line. At the same time, the signal at the end of the line is received by the second measuring point MS₂ and evaluated. The result is immediately transmitted to the first measuring point MS₁ via channel K2. The ratio may be used to determine the position of any leak that is present.

Also at the same time, the second measuring point MS₂ determines the impedance of channel K6 and relates same to the signal at measuring point MS₁. After the measurement is completed, the two measuring points MS₁ and MS₂ automatically switch to the next measurement channel. The signal processing upon which this is based is carried out, for example, according to a “direct sequence spread spectrum” method. Whether data channel K2 remains the same or is likewise changed depends on the expected influence between the measurement channel and the data channel.

The simultaneous measurement of both ends of the line segment may be carried out either by use of orthogonal signals or on the basis of corresponding channel division and synchronous demodulation in order to prevent influence. According to the invention, however, the use of a synchronous demodulator is the preferred method for determining the measurement signals, conditioned on minimization of the influence of spurious signals.

FIG. 4 shows the schematic sequence of measurement and data transmission between a first measuring point MSᵢ and a second measuring point MSⱼ, which represent two consecutive measuring points MSᵢ and MSᵢ₊₁ (j=i+1) in a plurality of measuring points Mᵢ situated along the electrical conductor L. Measuring point MSᵢ first transmits its measurement signal M(MSᵢ→MSᵢ₊₁) to a first channel and evaluates the impedance of the line (FIG. 4a). This measurement results in data set D[MS₁→MSᵢ₊₁), the left bracket indicating that this data set results from a measurement of MSᵢ after MSᵢ₊₁, starting at MSᵢ. At the same time, the signal at the end of the line is received by the second measuring point MSᵢ₊₁ and is evaluated as data set D(MS₁→MSᵢ₊₁]. The right bracket indicates that this data set results from a measurement of MSᵢ after MSᵢ₊₁, starting at MSᵢ₊₁. By use of the result signal E(MSᵢ→MSᵢ₊₁] the result is immediately transmitted to the first measuring point MSᵢ via a second channel (FIG. 4b). Measuring point MSᵢ then has a “complete” data set D[MS₁→MSᵢ₊₁] which results from an analysis of the measurement signal from both measuring points MSᵢ and MSᵢ₊₁, as indicated by brackets on both sides.

Simultaneously with the transmission of the result signal E(MSᵢ→MSᵢ₊₁], the second measuring point MSᵢ₊₁ determines the impedance of an additional channel by use of the measurement signal M(MS₁←MSᵢ₊₁) (FIG. 4b). This measurement results in data set D(MS₁←MSᵢ₊₁], the right bracket indicating that this data set results from a measurement of MSᵢ₊₁ after MSᵢ, starting at MSᵢ₊₁. At the same time, the signal at the end of the line is received by the first measuring point MSᵢ and is evaluated as data set D[MSᵢ←MSᵢ₊₁). The left bracket indicates that this data set results from a measurement of MSᵢ₊₁ after MSᵢ, starting at MSᵢ. By use of the result signal E[MSᵢ←MSᵢ₊₁) the result is immediately transmitted to the second measuring point MSᵢ₊₁ via a second channel (FIG. 4c). The measuring point MSᵢ₊₁ then has a “complete” data set D[MS₁←MSᵢ₊₁] resulting from an analysis of the measurement signal from both measuring points MSᵢ and MSᵢ₊₁, once again indicated by brackets on both sides.

FIG. 4d shows that the result of the impedance evaluation between the two consecutive measuring points MSᵢ and MSᵢ₊₁ is transmitted to at least one additional adjacent measuring point MSᵢ₋₁ or MSᵢ₊₂, so that by use of the result signal E[MSᵢ←MSᵢ₊₁] from the second measuring point MSᵢ₊₁, measuring point MSᵢ₊₂, for example, also has data set D[MSᵢ←MSᵢ₊₁]. Correspondingly, by use of the result signal E[MSᵢ→MSᵢ₊₁] the first measuring point MSᵢ may also transmit data set D[MSᵢ→MSᵢ₊₁] to second measuring point MSᵢ₊₁, which in turn relays this data set to measuring point MSᵢ₊₂ by use of the result signal E[MSᵢ→MSᵢ₊₁].

It is thus apparent that by use of this embodiment it is necessary to connect only one of the measuring points to a central control point 2 in which the measurement data are collected, processed, and evaluated, since each of the measuring points has all data sets. However, it is also possible for all data to be read out locally at one of the measuring points.

The evaluation of the distribution of the impedances as well as the determination of the leak take place via a higher-order control point 2. This control point is able to read the data, either in collected form from a measuring point MSᵢ or with appropriate linking of any given measuring point MSᵢ, and determine the expected leak by correlation. In addition, each individual measuring point MSᵢ is preferably able to make continuous predictions concerning the state of the pipe 1 by means of trend analysis of the measurement results.

Thus, by use of the method according to the invention it is possible to dispense with a complex process sequence control system as the result of omitting the alternating measurements and evaluation phases. In addition, it is no longer necessary for transmission of the measurement signals between two measuring points to take place only in an alternating manner; instead, simultaneous measurements from both ends of a pipe section are also possible. As a result, absolute or process-related measurement errors may be reduced, thereby increasing the accuracy of the leak location.

What is claimed is:

1. A method for identifying leaks in pipes for the transport of liquid or gaseous media by use of at least one electrical conductor extending along the longitudinal extension of the pipe from a first measuring point to a second measuring point, the method comprising:
transmitting a first measurement signal in the form of a temporally variable voltage from the first measuring point to the second measuring point via the electrical conductor;
evaluating the impedance of the electrical line at the first and second measuring points to determine the presence of a leak; and
transmitting a first result signal indicating the result of the impedance evaluation from the second measuring point to the first measuring point via the same electrical conductor such that the first result signal temporally overlaps the first measurement signal, and the first measurement signal and the first result signal are present in non-overlapping frequency bands.

2. The method according to claim 1, wherein the second measuring point transmits a second measurement signal in the form of a temporally variable voltage to the first measuring point via the same electrical conductor, and the first and second measuring points evaluate the impedance of the electrical line, wherein the first measuring point transmits the result of the impedance evaluation to the second measuring point with a second result signal via the same electrical conductor such that the second result signal temporally overlaps the second measurement signal, and the first and second measurement signals and the second result signal are respectively present in non-overlapping frequency bands.

3. The method according to claim 2, wherein the measurement signals and the result signals from the respective transmitting measuring point are subjected to modulation, and at the respective other receiving measuring point are evaluated by synchronous demodulation.

4. The method according to claim 1, wherein the first measuring point and the second measuring point are two consecutive measuring points in a plurality of measuring points situated along the electrical conductor, and the result of the impedance evaluation between the two consecutive measuring points is transmitted to at least one additional adjacent measuring point.

5. The method according to claim 4, wherein one of the measuring points transmits its measurement data to a central control point in which the measurement data are collected, processed, and evaluated.

6. A measuring device for identifying leaks in pipes for the transport of liquid or gaseous media, which is connected to at least one electrical conductor extending along the longitudinal extension of the pipe, comprising:
a signal generator configured to generate a measurement signal in the form of a temporally variable voltage, wherein the measurement signal is suitable for investigating the impedance behavior of the electrical conductor altered by a leak;
a transmitter configured to apply the measurement signal to the electrical conductor;
a generator unit configured to generate a modulation signal;
a baseband signal unit configured to generate a baseband signal; and
a modulator configured to mix the measurement signal, the baseband signal, and the modulation signal.

7. The measuring device according to claim 6, further comprising:
a receiver configured to receive modulated signals transmitted via the electrical conductor;
a demodulator;
a data separator; and
a measurement signal receiver coupled to the demodulator and being configured to digitally convert the measurement signal.
